(19) United States
(12) Patent Application Publication
(10) Pub. No.: US 2019/0271902 A1
(43) Pub. Date: Sep. 5, 2019

(54) SUPPORT FOR A TRIPOD

(71) Applicant: Really Right Stuff, LLC, San Luis Obispo, CA (US)

(72) Inventors: Verent CHAN, San Luis Obispo, CA (US); Brandon BRAY, San Luis Obispo, CA (US); Trevor JONES, San Luis Obispo, CA (US); Joseph M. JOHNSON, SR., San Luis Obispo, CA (US)

(21) Appl. No.: 16/232,777

(22) Filed: Dec. 26, 2018

Related U.S. Application Data
(60) Provisional application No. 62/637,344, filed on Mar. 1, 2018.

(51) Int. Cl. G03B 17/56; F16M 11/12; F16M 11/04

(52) U.S. Cl. CPC G03B 17/561; F16M 11/126; G01C 9/24; F16M 2200/041; F16M 11/041

(57) ABSTRACT

A head for supporting an imaging device and being supported by a tripod.

### CROSS-REFERENCE TO RELATED APPLICATIONS

This application claims the benefit of U.S. Provisional Patent Application 62/637,344 filed Mar. 1, 2018.

### BACKGROUND OF THE INVENTION

The present invention relates to a support for a tripod.

A tripod head is suitable for supporting an optical instrument, such as a film camera or a video camera. Typically, the tripod head includes a generally cylindrical housing, which has a connection mechanism at one end for a tripod. A ball member in the housing is movably engaged and is provided with a locking device at one end thereof for supporting the optical instrument.

Referring to FIG. 1, U.S. Patent Publication No. 2006/0175482 A1 discloses a tripod head that includes a body 100 and a ball 102. The ball 102 may include a stem 104 to which is attached a clamp 106. In many cases, the optical instrument includes a plate attached to the lower portion thereof. The plate is sized such that it is detachably engaged with the clamp 106, which selectively secures the plate. In some cases, the stem 104 includes a threaded opening therein or a threaded screw, which is detachably attached to the optical instrument. A ball knob 108, when turned clockwise, causes the ball 102 to be engaged and held in place, and hence inhibit the ball 102 from being rotated. The ball knob 108, when turned counter-clockwise causes the ball 102 to be disengaged, and hence readily permit the ball 102 to be rotated. A friction knob 110, when turned clockwise causes the ball 102 to be increasingly inhibited in its ability to move freely. The friction knob 110, when turned counter clockwise causes the ball 102 to be decreasingly inhibited in its ability to move freely. In operation, the friction knob 110 is primarily used to set a base friction on the ball 102 to inhibit its movement when the ball knob 108 is fully released by turning it counter clockwise. Then after positioning the optical instrument, such as a camera, the ball knob 108 is turned fully clockwise which increases the friction on the ball 102, normally sufficiently to maintain the optical instrument in position. A pan knob 112, when turned counter clockwise releases the body from a pan base 114, so that the body 100 may freely rotate in clockwise and counterclockwise directions. Then pan knob 114, when turned clockwise engages the body 100 with the pan base 114, so that the body 100 may not freely rotate in a clockwise and a counterclockwise direction.

Referring to FIG. 2, U.S. Pat. No. 8,596,892 discloses a tiltable mounting for a video camera comprising a base, a tiltable support member pivoted thereto, and a reactionary moment producing means located between and operated from the base and the tiltable support member to produce a reaction equal to the out of balance moment generated by the weight of an article mounted on the tiltable support member as the center of gravity moves about the vertical. The means for producing the reactionary moment comprises a horizontally extending spring guide mounted on the base carrying a compression spring acting between a slide and an end stop. The slide is eccentrically coupled to the support member with respect to the tilt axis so that tilting of support member with respect to the tilt axis so that tilting of the support causes the slide to compress the spring and produce a force to counterbalance the out of balance moment produced as the center of gravity of an article mounted on the tiltable support member rotates about the vertical. The spring guide has a rotary adjusting device connected to the guide by a lead screw to preload the spring in relation to the weight and position of the center of gravity of the article on the support which is located on a vertical member on the rearward side of the head.

### BRIEF DESCRIPTION OF THE DRAWINGS

FIG. 1 illustrates a tripod head.

FIG. 2 illustrates a tiltable mounting.

FIG. 3 illustrates a perspective view of another tiltable mounting.

FIG. 4 illustrates another perspective view of the tiltable mounting of FIG. 3.

FIG. 5 illustrates a rear view of the tiltable mounting of FIG. 3.

FIG. 6 illustrates a front view of the tiltable mounting of FIG. 3.

FIG. 7 illustrates a perspective view of yet another tiltable mounting.

FIG. 8 illustrates a top view of the yet another tiltable mounting.

FIG. 9 illustrates a perspective view of a further tiltable mounting.

FIG. 10 illustrates an enlarged view of a portion of the further tiltable mounting.

FIG. 11 illustrates a bubble head assembly.

FIG. 12 illustrates a rotary encoder assembly.

FIG. 13 illustrates a tilt lock assembly.

FIG. 14 illustrates a strain gauge assembly.

FIG. 15 illustrates a strain gauge needle based output.

FIG. 16 illustrates a counterbalance assembly.

FIG. 17 illustrates a counterbalance needle based output.

FIG. 18 illustrates a weight sensor assembly.

FIG. 19 illustrates a weight needle based output.

FIG. 20 illustrates a temperature assembly.

FIG. 21 illustrates a temperature needle based output.

FIG. 22 illustrates a battery sensor assembly.

FIG. 23 illustrates a battery sensor needle based assembly.

FIG. 24 illustrates a mounting with motors.

FIG. 25 illustrates a panning and tiling rotary encoder assembly.

FIG. 26 illustrates a dampening fluid assembly.

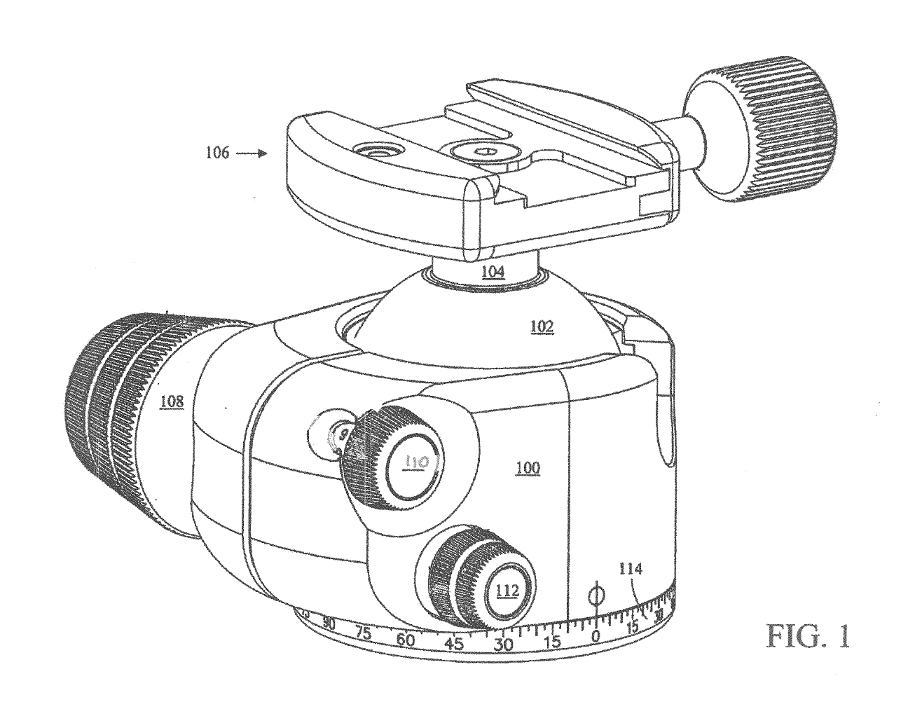

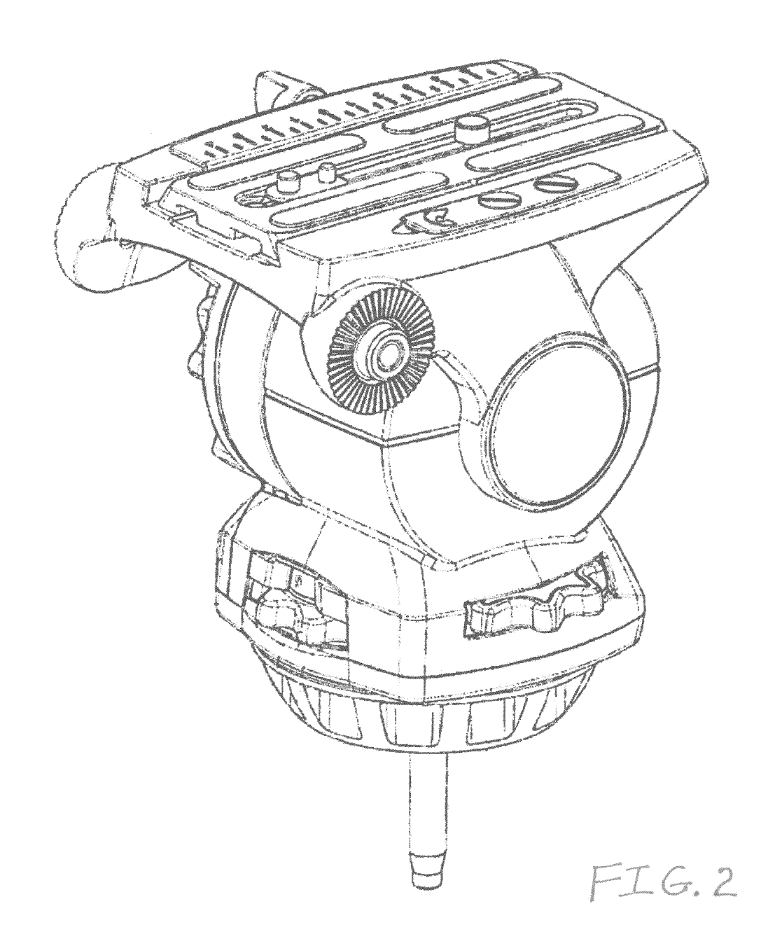

### DETAILED DESCRIPTION OF PREFERRED EMBODIMENTS

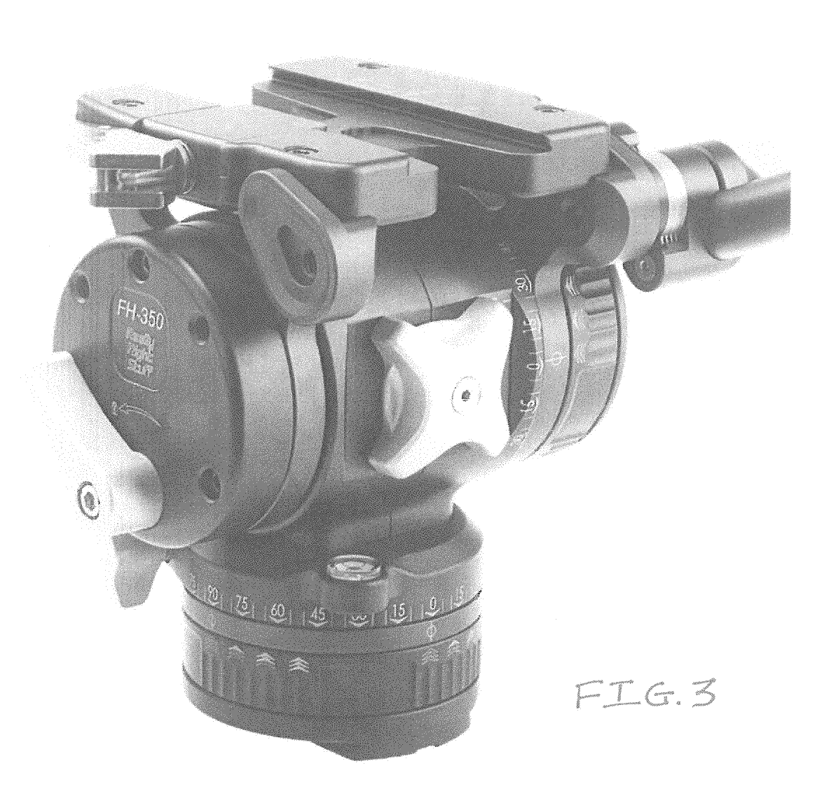

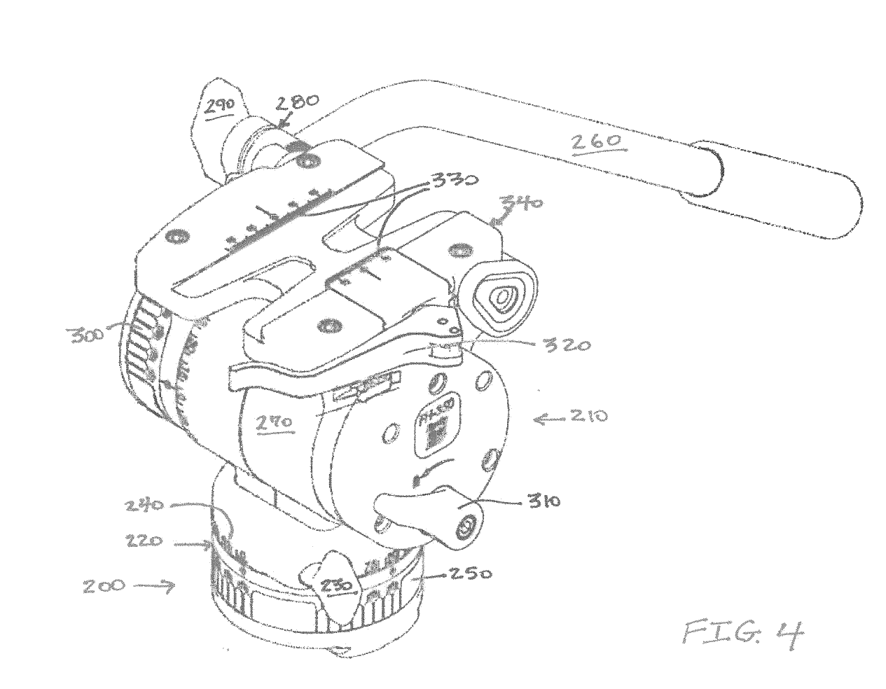

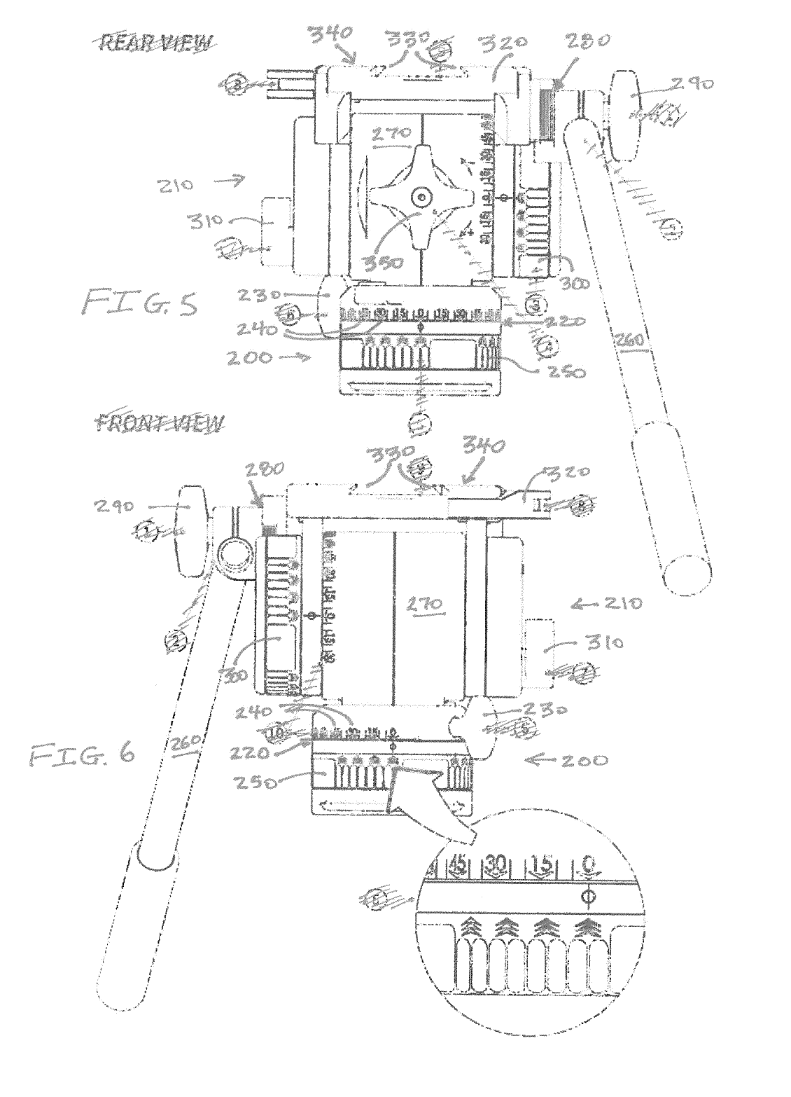

Referring to FIGS. 3, 4, 5, and 6 a mounting for an imaging device, such as a camera or video camera, includes a base 200 and a tiltable mounting assembly 210. The base 200 and tiltable mounting assembly 210 is supportable on a tripod, such as using a quick release clamp, or being screwed onto a screw extending up from a tripod. The tiltable mounting assembly 210 is rotatable with respect to the base 200 using a panning assembly 220. The tiltable mounting assembly 210 is rotatable around 360 degrees and includes a panning lock knob 230. The panning lock knob 230 may be turned clockwise to tighten the panning assembly 220 and increase inhibited rotation. The panning lock knob 230 may be turned counter-clockwise to loosen the panning assembly 220 and decrease inhibited rotation. The base 200 may include markings 240 to mark rotation in 15 degree increments. A pan damping adjustment wheel 250 increasingly increases and increasingly decreases the inhibition to panning rotation of the tiltable mounting assembly 210 by clockwise or counter-clockwise rotation, respectively, of the pan damping adjustment wheel 250. In this manner, the tiltable mounting assembly 210 may be inhibited from being rotated with respect to the base 200 to varying degrees.

The tiltable mounting assembly 210 includes a handle 260 that can be installed on either side of a head 270. The tiltable mounting assembly 210 includes a multi-lock swivel 280 that permits the handle 260 to be suitably positioned and then locked in position by turning a handle lock knob 290 in a first direction, and be repositioned by turning the handle lock knob 290 in an opposing direction to loosen. A tilt damping adjustment wheel 300 is rotatable to selectively increase and decrease the tilt damping of the tiltable mounting assembly 210 with respect to the base 200. A tilt lock lever 310 is rotatable to selectively lock the head 270 at any position and selectively loosen the head 270 from its locked position. A clamp lever 320 may be rotated to selectively open and close the jaws 330 of a quick release clamp 340. A counterbalance adjustment knob 350 is selectively rotatable to increase and decrease a counterbalance restoring torque of the tiling of the tiltable mounting assembly 210 with respect to the base 200.

To effectively use the mounting, the imaging device should be suitably balanced thereon. If the imaging device is not suitably balanced thereon, it is difficult to achieve a smooth tilting motion. To achieve a suitable balance a multi-step process may be undertaken. First, the base may be modified so that it is level with respect to the horizon, often using a level bubble. Second, after leveling the base, it is desirable to lock the panning base by rotating the pan lock knob clockwise to lock it. Third, after the rotating the pan lock knob, it is desirable to lock the tilt axis by rotating the tilt lock lever to the locked position. Fourth, after locking the tilt axis, it is desirable to turn off the tilt damping by rotating the tilt damping adjustment wheel to the off position. Fifth, after turning off the tilt damping, it is desirable to mount the imaging device (or a balance rail attached to the imaging device) by rotating the clamp lever until the jaw fully engages the imaging device and the clamp is in a fully closed and locked position. Sixth, after engaging the clamp lever, it is desirable to find a center of balance while holding the handle, unlocking the tilt axis, setting the head to zero degrees of tilt, and while holding the handle, determine if the head naturally wants to tilt forward toward the lens or rearward away from the lens. If the imaging device wants to tilt forward, then the load needs to be shifted backwards. If the imaging device wants to tilt rearward, then the load needs to be shifted forward. Shifting the imaging device is achieved by opening the clamp, adjusting the imaging device, and closing the clamp. Seventh, after shifting the imaging device, the counterbalance is set to its maximum by rotating the counterbalance adjustment knob clockwise until it comes to a hard stop at the maximum setting. Eighth, after maximizing the counterbalance, the head it tilted forward 15 to 30 degrees. Ninth, while holding the imaging device tilted forward, the counterbalance adjustment knob is rotated counterclockwise until the resistance is reduced and the head stays in its tilted position without user support. If the head falls under the weight of the imaging device, the counterbalance is increased by rotating the adjustment knob. If the head springs back toward zero tilt, the counterbalance is decreased by the adjustment knob. When property set, the imaging device stays in any tilt position without requiring user input. Tenth, the dampening is adjusted by rotating the damping adjustment wheel to the desired setting.

As it may be observed, the process by which the settings are adjusted is time consuming, is prone to being repeated multiple times to obtain a suitable adjustment, and requires a high degree of skill by the user. A simplified manner in which the mounting assembly may be adjusted is desirable, so that a more consistent setting may be achieved, while not requiring such a degree of skill by the user.

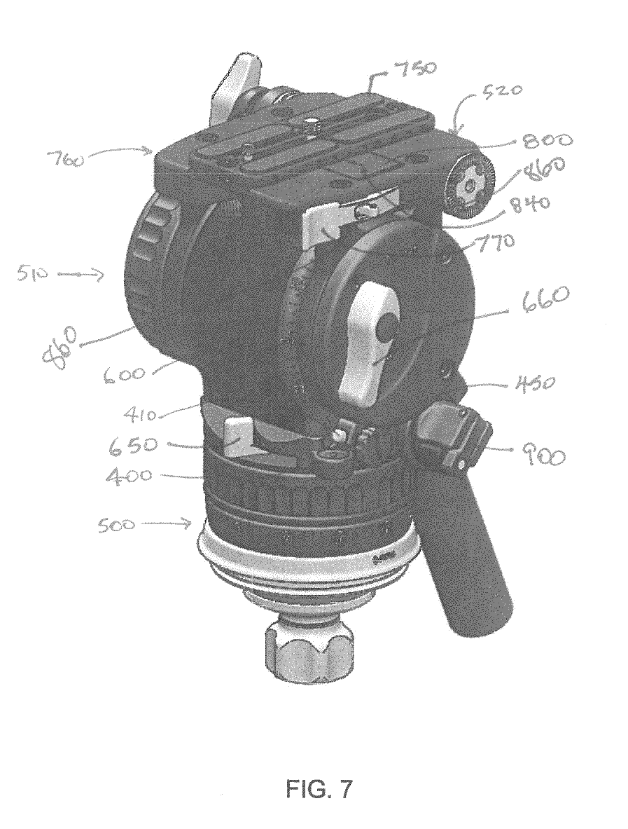

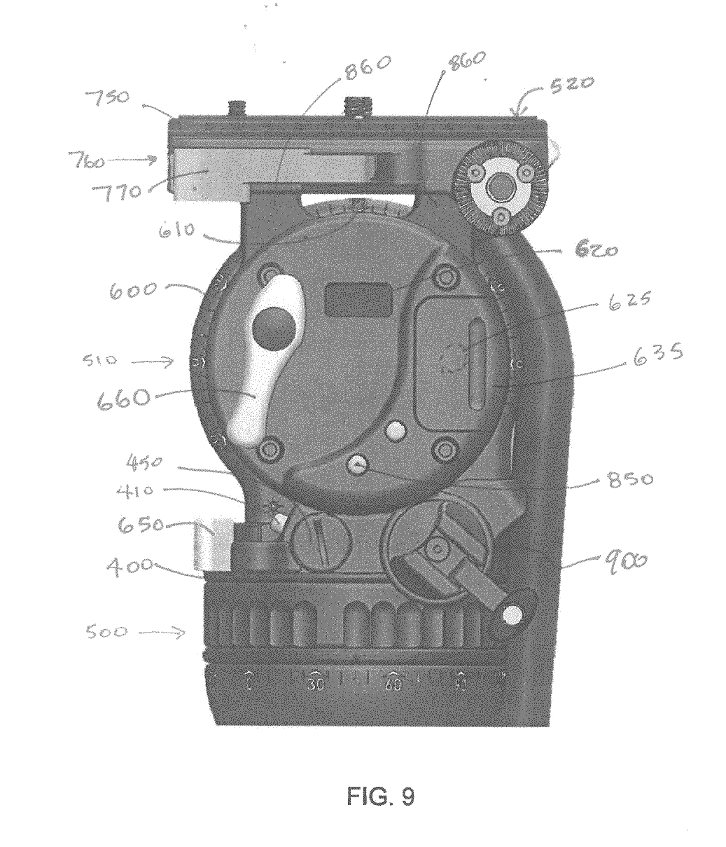

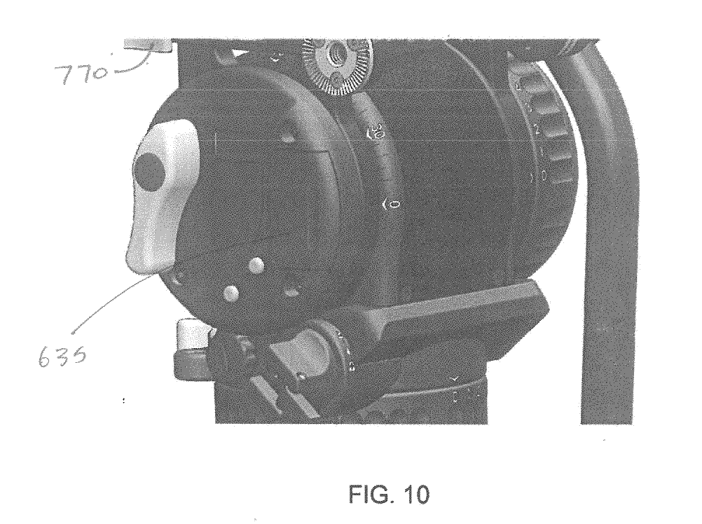

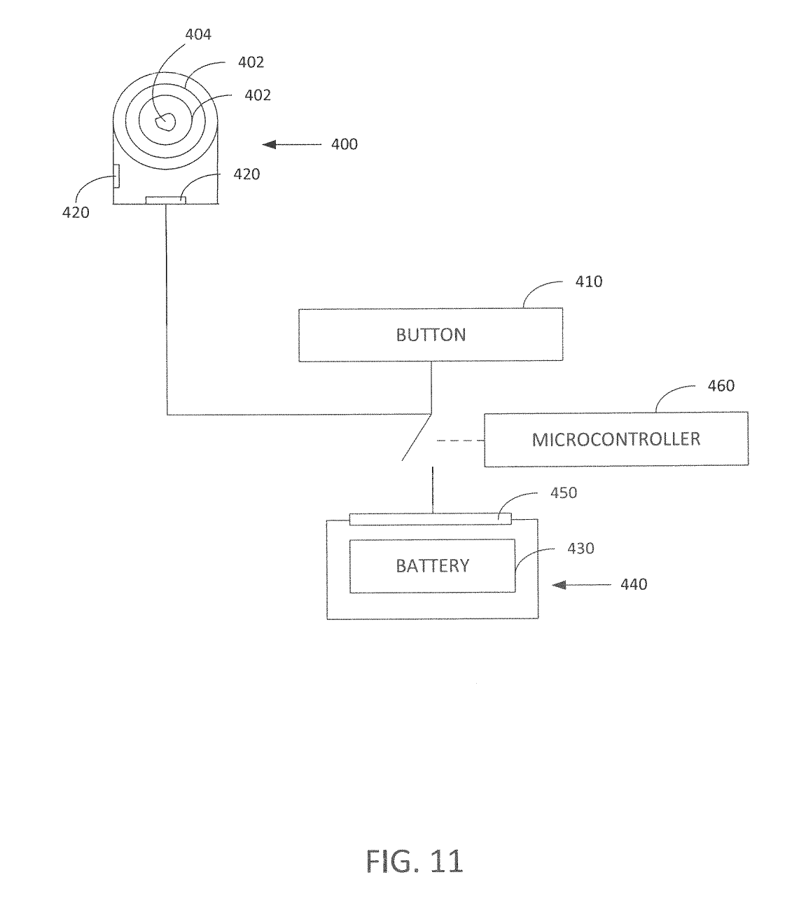

Referring to FIG. 7, FIG. 9, and FIG. 11, a modified mounting may include a bubble level 400 that preferably includes one or more concentric rings 402 with a bubble 404 maintained within. Other structures and arrangements of levels may likewise be used. When the bubble in the bubble level 400 is centered, with the bubble level being co-planar with a base 500, the base 500 is level. In some environments, the bubble level is difficult to see such as in the night or in indoor low lighting level environments. While a flashlight may be used to illuminate the bubble level this may be distracting to others in an indoor environment or otherwise disturb others in an outdoor setting, such as nearby animals. To provide a controlled lighting environment, the mounting preferably includes a button 410 that may be depressed which results in a light emitting element(s) 420, such as a light emitting diode, to illuminate the bubble level 400 from its side and/or lower surface. A slider, switch, touch sensitive member, or other structure may be used to selectively illuminate the bubble level 400 from its side and/or lower surface. In this manner, a controlled amount of lighting may be provided to the bubble level so that the base may be leveled in low light environments without unnecessarily disturbing the environment. Preferably, after depressing the button 410 or otherwise, the light remains illuminated for a predetermined period of time, such as 15 seconds. Alternatively, after depressing the button 410 or otherwise, the light remains illuminated until the button 410 is depressed again. Alternatively, after depressing the button 410 or otherwise, the light remains illuminated while the button 410 remains depressed. By providing a controlled manner of illumination, a battery 430 for the illumination may not be unnecessarily drained by inadvertently leaving the light illuminated for a prolonged period of time. A battery housing 440 may be provided on the tiltable mounting assembly (e.g., head) 510 or the base 500, which encloses the battery 430 therein and electrically interconnects the battery 430 to the light emitting element(s) 420. Preferably the battery housing 440 includes a cover 450 that is detachably engageable by rotation, such as rotation clockwise for engagement and rotation counter-clockwise for dis-engagement. The battery is preferably a 3 volt CR1632 lithium battery. In general, any trigger mechanism may be used to selectively interconnect the battery source with the illumination source, including without limitation a microcontroller 460 providing the interconnection.

After the base 500 is leveled, preferably using the bubble level 400, the top 520 of the head 510 is preferably adjusted until it is in co-planar arrangement with the base 500. As illustrated in FIG. 7 and FIG. 9, a set of angular markings 600 may be included on the head 510 to indicate the degree of rotation of the top 520 of the head 510 with respect to being co-planar with the base 500. For example, a 0 degree or a 90 degree angular marking aligned with the top 520 of the head 510 may indicate a co-planar orientation. Other angular markings on the head 510 relative to the base 500 may be used to indicate a co-planar orientation between the top 520 of the head and the base 500.

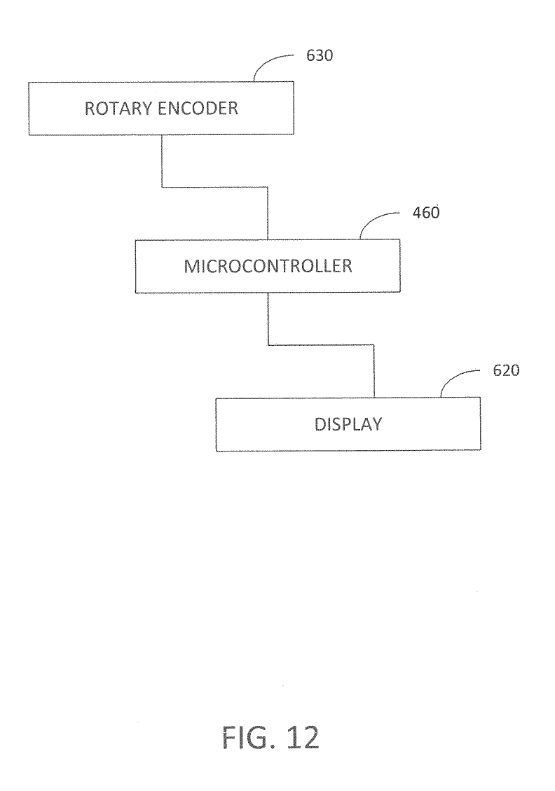

As illustrated in FIG. 9, a head that includes additional electronics may include a digital display 620 thereon that is viewable from the exterior of the head. Signals may be provided to the digital display 620 from the microcontroller 460, if desired. Also referring to FIG. 12, a rotary encoder 630 included within the head may indicate a degree of tilting rotation of the head on the display 620. Preferably, the rotary encoder 630 provides inputs to the microcontroller 460 which in turn provides data to be displayed on the display 620. By way of example, the rotary encoder may display the tilting rotation of the head as a degree of rotation, such as 0 degrees, 15 degrees, 30 degrees, 45 degrees, −15 degrees, −30 degrees, −45 degrees, or as a sequential number of integers from 0 degrees to a maximum number of degrees of rotation. For example, a 0 degrees of rotation may indicate that the base is in a co-planar orientation with the top of the head. As illustrated in FIG. 9, the head may also include angular markings 610 to indicate a degree of rotation between the top of the head and the base. With the rotary encoder 630 with the display 620 in combination with a set of angular markings 610 this provides increased flexibility for the user ensuring that the top of the head and the base are both in a co-planar, or other, orientation with respect to one another. In addition, preferably both the display and the angular markings are viewable from the same side of the head. Moreover, preferably both the display and the angular markings are viewable from a side of the head perpendicular to the axis of rotation of the head.

After leveling the base 500, it is often desirable to inhibit the rotation of the head 510 with respect to the base 500 by engaging a pan lock lever 650. By movement of the pan lock lever 650 in a clockwise direction, the head 510 is increasingly inhibited from rotation with respect to the base 500. By movement of the pan lock lever 650 in a counter-clockwise direction, the head 510 is decreased from being inhibited from rotation with respect to the base 500. Other structures may likewise be used to selectively inhibit rotation of the head 510 with respect to the base 500.

With the top of the head and the base being aligned in a co-planar orientation it is desirable to lock the relative movement of the base and the head so that an imaging device may be supported thereon in a secure manner. A tilt lock lever 660 may be turned in a counter-clockwise manner from a locked orientation where the head and the base are not freely movable with respect to one another to an unlocked orientation where the head and the base are freely movable with respect to one another. Also, the tilt lock lever 660 may be turned in a clockwise manner from an unlocked orientation where the head and the base are freely movable with respect to one another to a locked orientation where the head and the base are not freely movable respect to one another. Referring also to FIG. 13, when the tilt lock lever 660 is moved from an unlocked orientation to a locked orientation 710 or otherwise maintained in a locked orientation 720, a tilt lock sensor 700 maintained within the mounting automatically determines that the head 510 is in a ‘safe’ position 730 for receiving the imaging device thereon, especially when the angle is generally between 0 degrees and 15 degrees. The tilt lock sensor 700 may be interconnected to the microcontroller 460 if desired, or otherwise may be part of the microcontroller, if desired. Alternatively, a mechanical structure maintained within the mounting may automatically determine that the head is in a ‘safe’ position for receiving the imaging device thereon based upon movement of the tilt lock lever 660 and/or the position of the tilt lock lever 660. Preferably, a tilt dampening mechanism is released or otherwise turned off, described later.

With the top of the head and the base being in a co-planar orientation, it is desirable to support the imaging device thereon because it is less likely that the imaging device will fall off the mounting or otherwise cause a supporting tripod to fall over with such an orientation. In many embodiments, the imaging device will include a plate 750 on the bottom thereof, or otherwise a dovetail structure on the bottom thereof, that is engageable with a quick release mechanism 760. One exemplary quick release mechanism is U.S. Pat. No. 6,773,172 entitled “Quick-Release Clamp for Photographic Equipment” incorporated by reference herein in its entirety. Other structures may likewise be used to detachably engage the imaging device with the top of the head.

The imaging device is normally moved backward and/or forward a limited distance within the quick release mechanism 760 by selectively releasing the engagement of the quick release mechanism to the imaging device to generally position the center of gravity of the imaging device on the mounting. After the center of gravity of the imaging device is generally centered on the mounting, the imaging device is secured in place by locking a lever mechanism 770. Locking the lever mechanism 770 causes jaws of the quick release clamp to move toward one another thereby securing the imaging device, and releasing the lever mechanism 770 causes jaws of the quick release clamp to move away from one another thereby releasing the imaging device. Other structures, such as screws with a knob, may be used to detachably secure the imaging device with the top of the head.

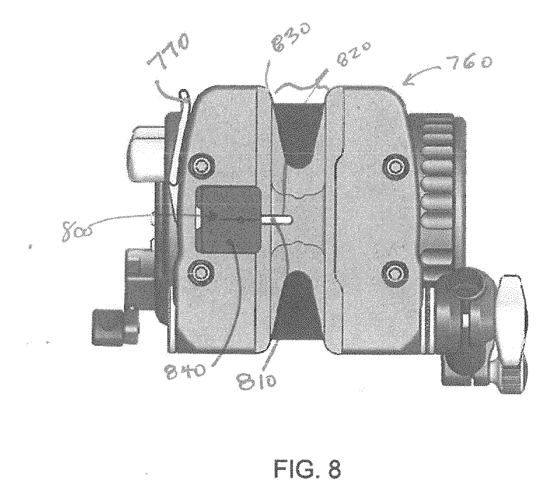

Unfortunately, until the imaging device is properly secured in position it occasionally becomes detached from the quick release mechanism 760 and falls to the ground which damages the imaging device, which is especially troublesome for heavier imaging device like a professional broadcast video cameras. To decrease the likelihood that the imaging device will become inadvertently detached from the quick release mechanism 760 a safety lock mechanism 800 may be automatically engaged to at least partially inhibit the imaging device from becoming detached from the quick release mechanism 760. Referring also to FIG. 8, the safety lock mechanism 800 may include a pin 810 that extends into a slot 820 of the quick release mechanism 760. When the plate 750 or the imaging device is engaged with the slot 820, it presses down on the pin 810 which lowers into a depression 830 defined by the quick release mechanism 760. The pin 810 is interconnected to a plate 840 so that when the pin 810 is lowered into the depression 830, the plate 840 is lowered or otherwise tilted, resulting in the plate 840 at least partially engaging the plate 750 or otherwise the imaging device to inhibit the imaging device from becoming detached from the mounting. In this manner, the action of positioning an imaging device within the quick release clamp will automatically result in at least a partial engagement of the imaging device to at least partially inhibit the imaging device from becoming detached from the quick release clamp. This significantly decreases the likelihood that the imaging device will become inadvertently disengaged from the quick release mechanism, with the weight of the imaging device causing the clamp 760 to engage the plate 750. The imaging device may be disengaged from the clamp 760 by lifting the imaging device, which releases pin, which in turn releases the plate 840 from the imaging device. After the imaging device is positioned in a suitable location, the lever mechanism 770 securely locks the imaging device to the quick release mechanism 760.

While the imaging device is generally centered on the mounting and generally positioned with its center of gravity being centered, it is often desirable to adjust its lateral position to more accurately center the center of gravity of the imaging device on the mounting, which tends to vary for each imaging device depending on the particular lens affixed thereto. The imaging device may be adjusted by repeatedly loosen the clamp 760, adjusting the lateral position of the imaging device, and securing the clamp 760. To more accurately determine a suitable position of the imaging device, such in a centrally balanced position on the mounting, a button 850 may be depressed to indicate a desirability to measure the balance of the imaging device. Preferably, the button 850 is operational only when the mounting determines it is in a “safe” position, as previously described. The button 850 may be any other suitable trigger mechanism, as desired.

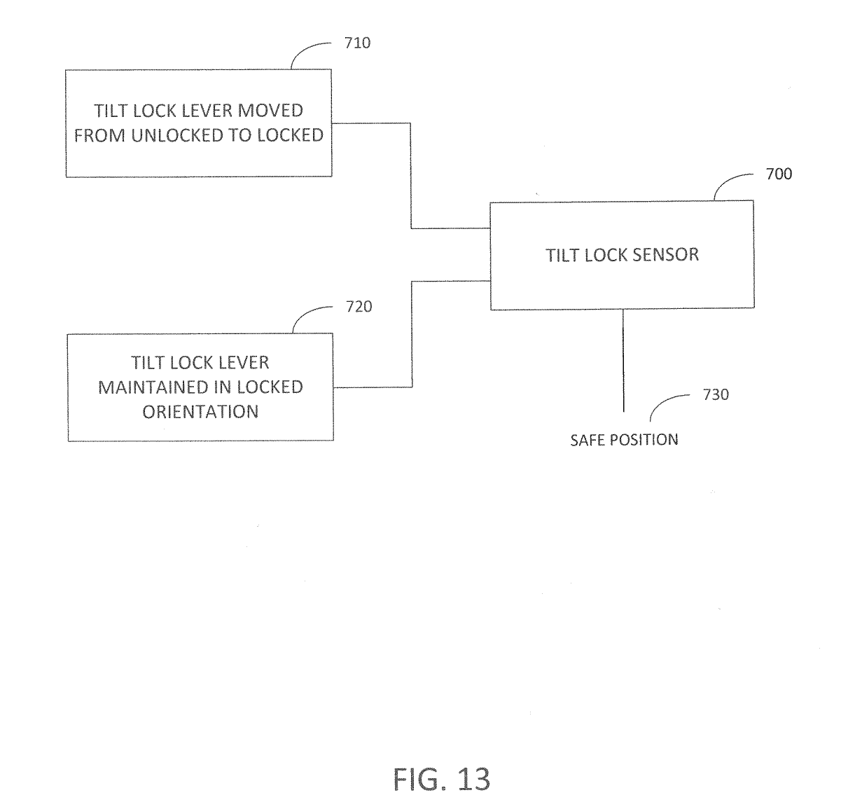

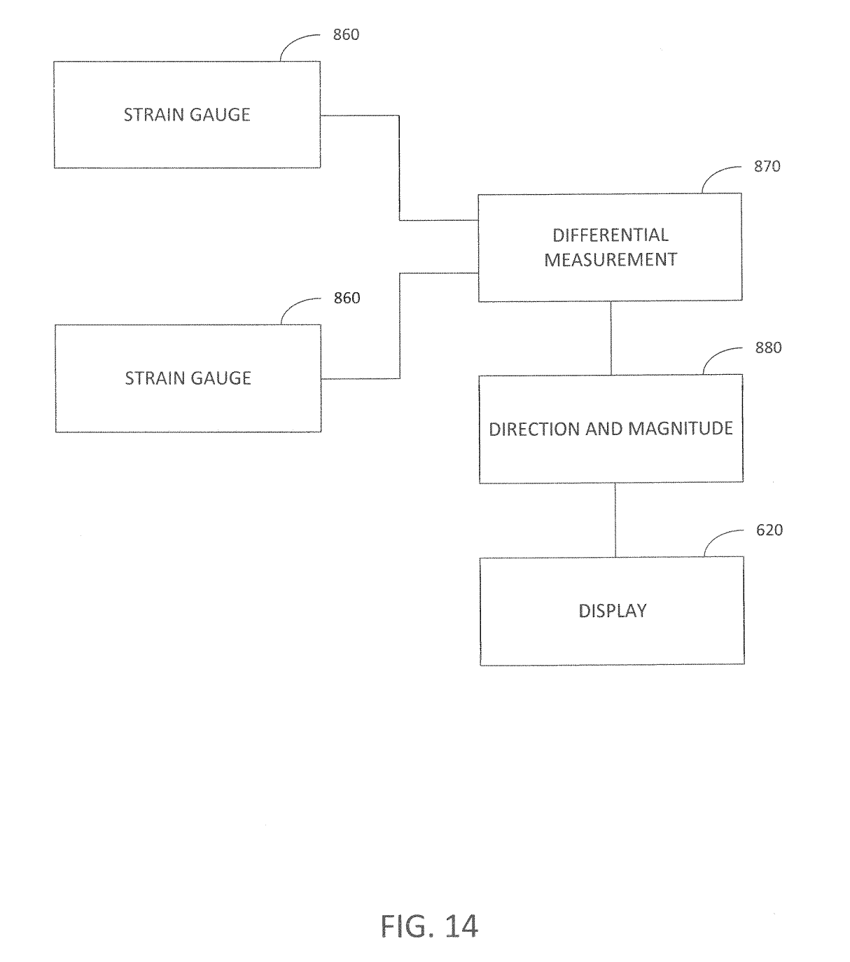

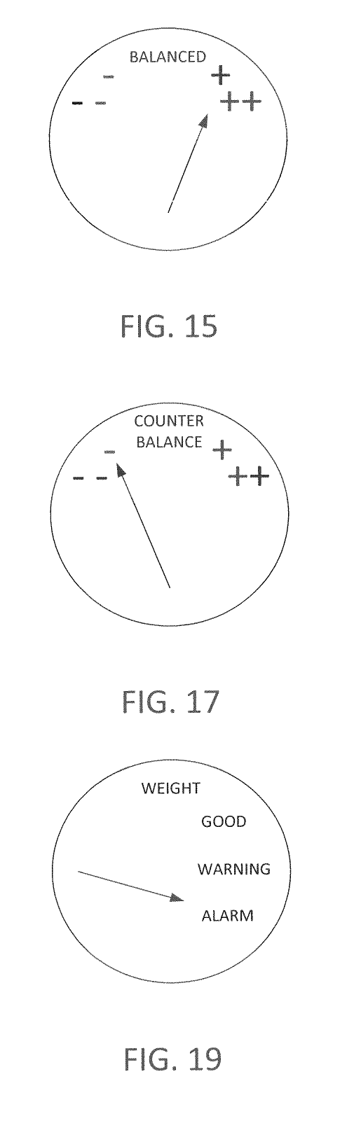

By depressing the button 850, preferably while the mounting is in a “safe” position, a pair of strain gauges 860 maintained within a respective pair of risers affixed to each side of the quick release mechanism 760 may be used to provide a suitable indication. If the mounting is not in a “safe” position, then the mounting preferably waits after depressing the button 850 until it is determined that the mounting is in a “safe” position, such as by the safe position 730. The pair of strain gauges 860 may be used to measure the stretch and/or the compression of each side of the quick release mechanism 760 aligned with the direction of the tilt of the head. Referring also to FIG. 14, a differential measurement 870 may be determined based upon the output of each of the strain gauges 860. The output of the differential measurement 870 may be used to determine a direction 880 that the imaging device should be shifted. By way of example, the differential measurement 870 may be determined by the microcontroller 460. For example, if one strain gauge is in compression and the other strain gauge is in stretch, then the imaging device is preferably moved in the direction of the strain gauge that is in stretch. Also, a magnitude 880 of the differential measurement 870 may be used to determine the magnitude 880 amount of shifting of the imaging device. The direction of the shift may be indicated on the display 620, such as with a + or − sign, or a directional arrow. The magnitude of the shift may be indicated on the display 620, such as with a small icon, a medium icon, a large icon, or a numerical number. By way of example, the balance may be displayed as a pair of arrows indicating a direction of movement, a central balance point, and an “O” indicating the balance location (e.g., < - - - - - O - | - - - - - - - >). Referring to FIG. 15, alternatively, a mechanical structure, such as a needle within a circular housing may be used to indicate the direction (e.g., which direction the needle is leaning from vertical) and the magnitude of the shift (e.g., the amount the needle is leaning from vertical). Alternatively, a single strain gauge may be used to measure the compression and/or stretch. Alternatively, other structures than the one or more strain gauges may be used to measure the balance of the imaging device on the head thereof. Also, the “safe” position may further include the panning being locked, or otherwise inhibited from rotation.

Accordingly, based upon the display, a determination may be made whether an adjustment is desirable and, in the case that an adjustment is desirable, indicate whether the imaging device should be moved forward or backward, and to what extent, if desired. Accordingly, based upon a mechanical structure, the deflection and direction of a needle (or other structure) may be used to indicate whether the imaging device should be moved forward or backward, and to what extent by the amount of deflection of the needle, if desired. Once the desired balance point has been reached, the clamp jaw should be locked in place to secure the imaging device to the quick release mechanism. To further prevent the imaging device from becoming inadvertently detached from the quick release clamp, a safety latch 720 may be included, which locks the lever mechanism 770 from unlocking. The safety latch 720 may be configured to automatically lock upon closing of the lever mechanism 770 or may be locked upon lateral movement after closing of the lever mechanism 770. Also, lateral movement of the safety latch 720 may unlock the lever mechanism 770 from being locked.

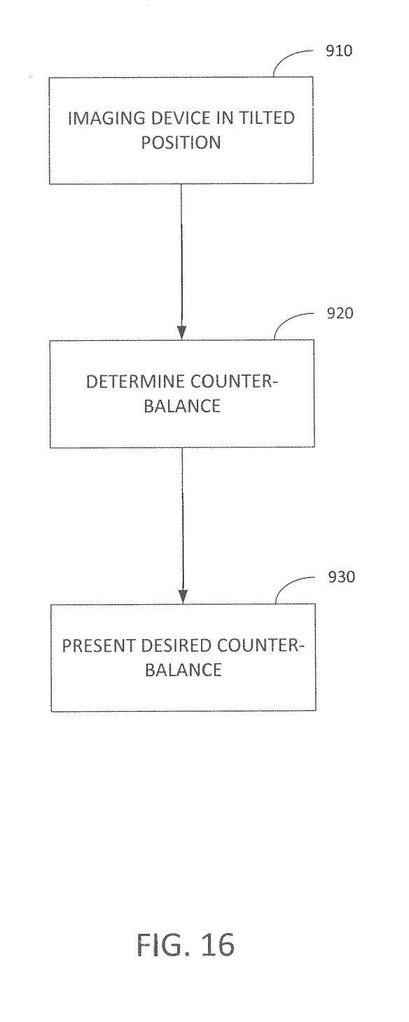

Preferably after the imaging device has been balanced on the head, to determine a suitable counter balance setting, the tilt lock lever 660 may be unlocked and the head is turned to a predetermined orientation, such as a generally 45 degree orientation. The 45 degree orientation may be determined based upon the markings and/or the rotary encoder. Other orientations may likewise be used, as desired. The tilt lock lever 660 may be locked after the desired orientation is obtained. The locking of the tilt lock lever 660, especially at an angle generally between 15 and 75 degrees, indicates to the that the mounting is in a safe position. Moreover, the “safe position” may be distinguished between being at generally around 0 to 15 degrees for supporting the imaging device therein for balance, and being at generally around 15 to 75 degrees for adjusting the counterbalance, as desired. Referring also to FIG. 16, while the imaging device is generally oriented at 45 degrees on the mounting 910, it is often desirable to adjust its counter balance to more smoothly adjust the imaging device on the mounting, which tends to vary for each imaging device depending on the particular lens affixed thereto. The counter balance of the imaging device may be adjusted by adjusting a counter balance knob 900 for either more or less restoring torque. To more accurately determine the position of the imaging device, such in a suitable counter balanced position on the mounting 920, a button 750 may be depressed to indicate a desirability to measure the counter balance of the imaging device. The determining of the counterbalance is preferably using the microcontroller 460. The selection of the button 750, while in the safe position, and more preferably while in the tilted safe position (e.g., 15 to 75 degrees), may be enabled for adjusting the counter balance. Upon pressing the button 750 a measurement is obtained of the torque required to hold the imaging device in the selected position, and the microcontroller 460 calculates a desired counter balance value for the user. The desired counter balance 930 may be displayed on the display 620, preferably using the microcontroller 460. A different button or otherwise may be used, as desired. The user may adjust the counter balance knob 900 for either more or less restoring torque, and the display 620 will indicate how much counter balance is being used. The display may also indicate whether more or less counter balance is suitable. The display may also indicate the amount of more or less counter balance is suitable. Referring to FIG. 17, in the case of a mechanical structure, the user may adjust the counter balance knob 900 for either more or less restoring torque, and an indicator, such as a needle, will indicate how much counter balance is being used. In the case of a mechanical structure, the indicator may also indicate whether more or less counter balance is suitable. In the case of a mechanical structure, the indicator may also indicate the amount of more or less counter balance is suitable. A dampening knob may be tightened or loosened, if desired.

In one embodiment, one or more strain gauges may be used to measure the weight of the imaging device at a first position, such as with the head in a horizontal position. The one or more strain gauges may be used to measure the weight of the imaging device at a second position, such as with the head in a tiled position (e.g., 45 degrees). With the microcontroller 460 making a comparison between the strain measurements at the first and second positions, the torque that results from the imaging device's offset may be determined. Based upon the determined torque the mounting may automatically adjust the amount of counterbalance for the mounting. For example, the amount of restoring torque determination may be based upon a cross-reference look-up table to select a suitable counterbalance setting. The determination of a suitable restoring torque determination may further be based upon the particular imaging device and/or imaging device and lens combination, if desired. The particular imaging device and/or imaging device and lens combination may be programmed into the mounting device, such as through the display interface. In addition, the display 620 may provide the recommended setting for the counterbalance and the current real-time setting of the counterbalance, so a comparison may be made by the user.

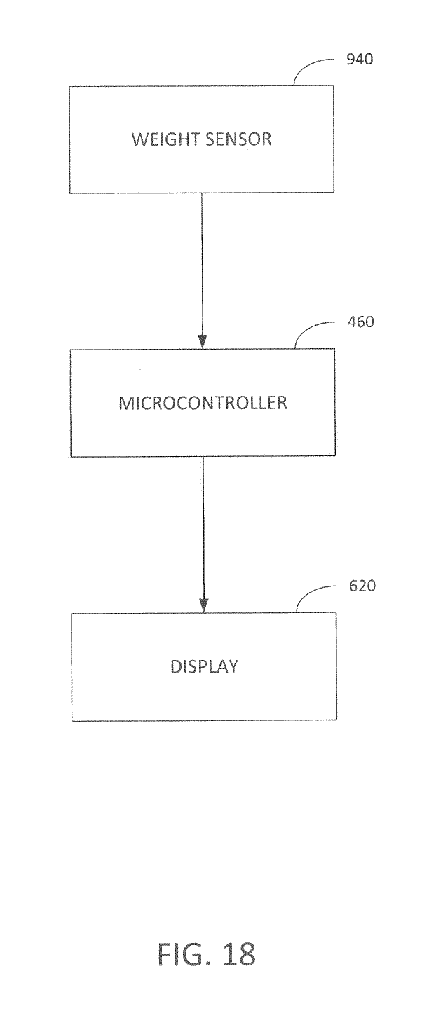

For some imaging devices the mechanics and size of the mounting may be generally inadequate to suitably maintain a desired tilting and a desired counterbalance. In such cases, the imaging device generally has a weight greater than the mounting was designed to suitably provide control over. Typically, the excess weight results in more counter balance being needed than the mounting is capable of readily providing. As illustrated in FIG. 18, a weight sensor 940 may be included within the mounting to sense the weight of the imaging device supported thereon. While the weight sensor 940 may be a separate sensor, the weight sensor 940 may also be incorporated with the strain gauge(s) or incorporated as a separate strain gauge. In addition, the weight may be based upon the tilt of the head, to adjust for differences as a result of different tilts in the head relative to the base. In the case that the imaging device is sufficiently high and over a weight limit an alarm condition may be indicated to the user. In the case that the imaging device is nearly sufficiently high but still insubstantially under the weight limit a warning condition may be indicated to the user. The processing of the weight data and the conditions may be performed by the microcontroller 460. The alarm condition is preferably provided on the display 620. The warning condition is preferably provided on the display 620. Referring to FIG. 19, the alarm condition may likewise be indicated by a needle, if desired. The warning condition may likewise be indicated by a needle, if desired.

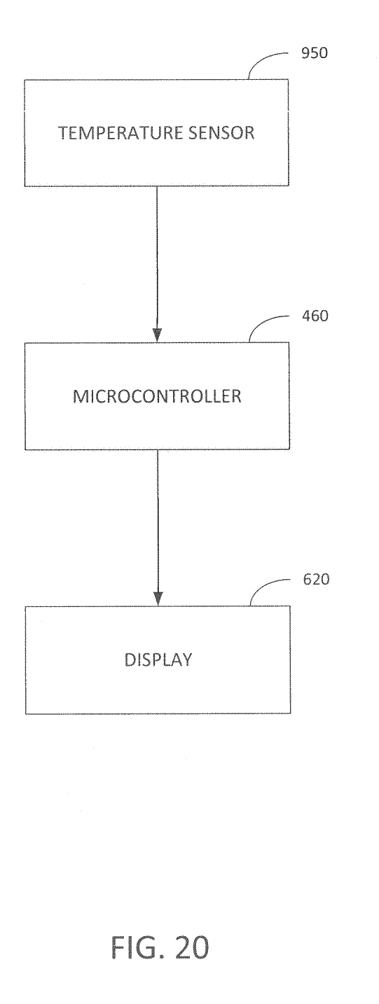

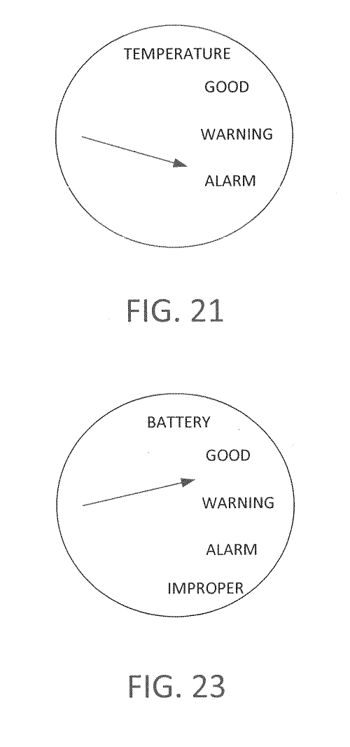

For some imaging devices the temperatures of the ambient environment that are suitable for its optimal use, and for the mounting that includes mechanical and/or electrical components thereof, the ambient environment should be within a suitable operational temperature range. By way of example, there may be a lower ambient temperature where the operation of the system (e.g., mounting and/or imaging device) should be greater than a predetermined temperature. By way of example, there may be an upper ambient temperature where the operation of the system (e.g., mounting and/or imaging device) should be less than a predetermined temperature. As illustrated in FIG. 20, a temperature sensor 950 may be included within the mounting to sense the temperature of the environment of the mounting and/or imaging device supported thereon. In the case that the ambient environment of the mounting and/or imaging device is sufficiently high and/or sufficiently low, such as a high temperature alarm level and/or a low temperature alarm level, respectively, an over temperature and/or below temperature alarm condition may be indicated to the user. In the case that the ambient environment of the mounting and/or imaging device is moderately high and/or moderately low, such as a moderate high temperature warning level and/or a moderate low temperature warning level, respectively, an over temperature and/or below temperature warning condition may be indicated to the user. The processing of the temperature data and the conditions may be performed by the microcontroller 460. The alarm condition is preferably provided on the display 620. The warning condition is preferably provided on the display 620. Referring to FIG. 21, the alarm condition may likewise be indicated by a needle, if desired. The warning condition may likewise be indicated by a needle, if desired.

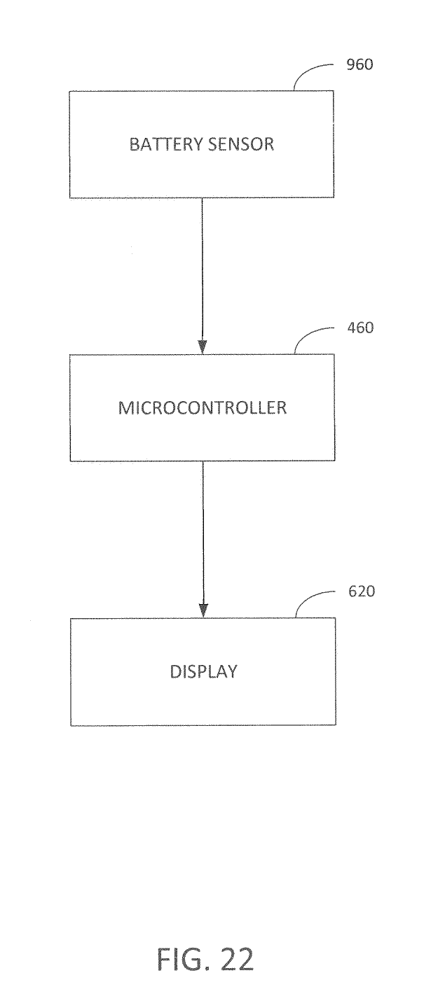

For some applications, such as an extended polar expedition, it is desirable that the battery does not become fully drained during the expedition thus rendering the electronics of the mounting to be non-operational. Referring to FIG. 22, to alleviate the likelihood of the battery becoming fully drained, the electronics within the mounting, and preferably the microcontroller 460, monitor the battery using a battery sensor 960 (which may be part of the microcontroller 460) to determine its anticipated battery life, such as during normal usage. The processing of the battery data and the conditions may be performed by the microcontroller 460. By way of example, there may be a lower anticipated battery life threshold where the battery is preferably replaced, such as when the threshold reaches 6 months. By way of example, there may be a warning anticipated battery life threshold where the battery is not yet preferably replaced, such as when the threshold reaches 3 months. In the case that the anticipated battery life is below a threshold, such as 6 months and 3 months, an alarm and a warning condition may be indicated, respectively, to the user. The alarm condition is preferably provided on the display 620. The warning condition is preferably provided on the display 620. Referring to FIG. 23, the alarm condition may likewise be indicated by a needle, if desired. The warning condition may likewise be indicated by a needle, if desired.

In addition, the battery sensor 960 may be used by the microcontroller 460 to determine whether an improper battery has been installed in the battery component which may result in improper operation of the mounting and/or damage the electronics housed by mounting. In the event that an improper batter is sensed within the housing, a battery type alarm may be provided on the display 620 (see FIG. 22) or otherwise indicated by a needle (see FIG. 23).

The rotary sensor is preferably based upon an absolute position of the head with respect to the base. With the rotary sensor being based upon an absolute position, if the battery power to the mounting is interrupted or otherwise temporarily removed, upon resuming battery power to the mounting the rotary sensor will provide an accurate measurement. Moreover, this measurement will still be accurate even if the head is tilted relative to the base while the battery power is interrupted. This characteristic of the rotary sensor avoids the need for recalibration even if the battery power is interrupted.

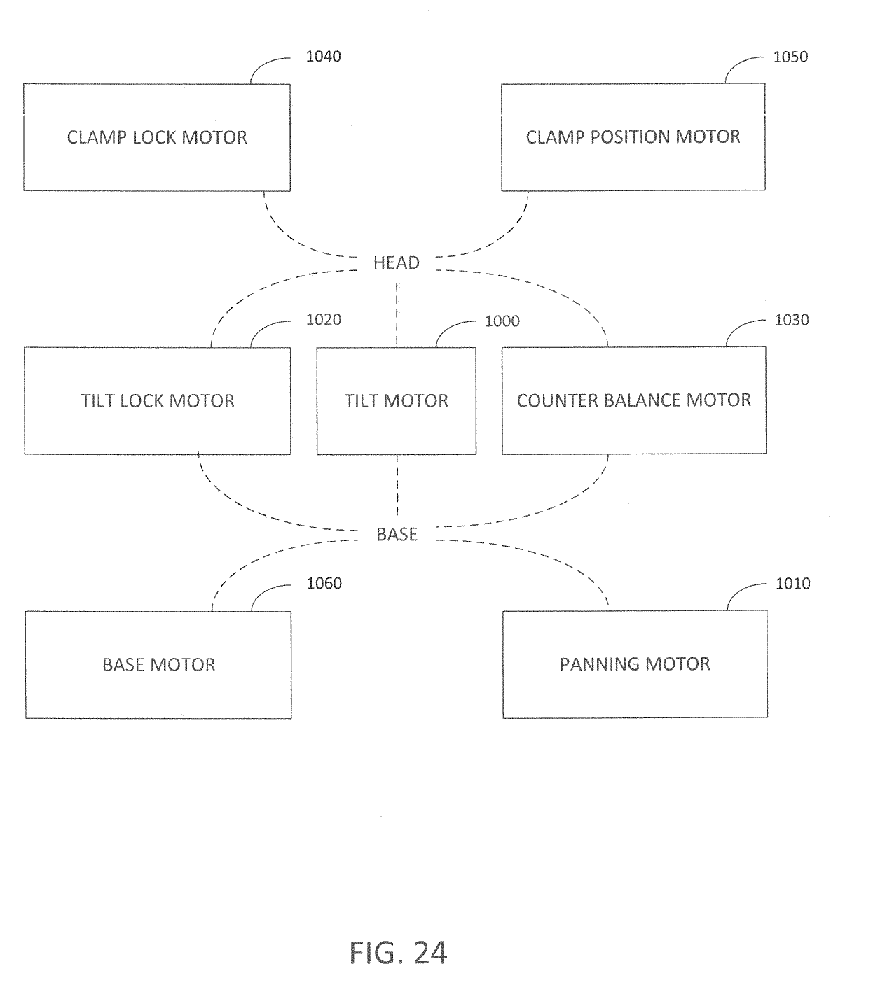

To provide further ease of calibration a set of one or more motors may be included with the mounting. Referring to FIG. 24, a tilt motor 1000 may be included that is suitable to adjust the tilt of the head relative to the base along an angular path. For example the tilt motor 1000 may adjust the tilt in a clockwise direction and a counterclockwise direction. A panning motor 1010 may be included that is suitable to adjust the panning rotation of the head relative to the base along a path generally perpendicular to the angular path of the tilt motor 1000. For example the panning motor 1010 may adjust the rotation of the head relative to the base in a first rotary direction and a second rotary direction opposite to the first rotary direction. A tilt lock motor 1020 may be included that is suitable to adjust the tilt lock between a position that inhibits rotation of the head relative to the base and a position that doesn't inhibit the rotation of the head relative to the base. A counterbalance motor 1030 may be included that is suitable to adjust the counterbalance of the head relative to the base. A clamp lock motor 1040 may be included that is suitable to adjust the locking of the clamp between a locked and an unlocked position. A clamp position motor 1050 may be included that is suitable to adjust the lateral position of the imaging device and/or plate within the clamp. A base motor 1060 may be included that adjusts the planarity of the base with respect to being level. Depending on the particular implementation, one or more of the motors may be replaced with other electrically operated structures that achieve the same function, such as for example, solenoids, switches, etc. With the addition of one or more motors, together with the microcontroller 460, the mounting may be adjusted from one state to another state in a manner suitable for being configured and/or automatically be adjusted from one state to another state in a manner suitable for being configured.

By way of example, the base motor 1060 may be modified so that it is level with respect to the horizon based upon a level sensor. After leveling the base using the base motor 1060, preferring the panning motor 1010 is used to lock the panning base. After locking the panning base with the panning motor 1010, the tilt axis may be adjusted to a horizontal position by the tilt motor 1000 and locked in place by the tilt lock motor 1020 (or otherwise the tilt motor 1000). The clamp lock motor 1040 preferably opens the clamp to be in a position suitable to receive the imaging device thereon. With the imaging device then supported by the mounting, which may be readily determined by a weight sensor, it is desirable to lock the clamp using the clamp lock motor 1040. With the imaging device secured on the mounting, as determined based upon the clamp being locked and/or the weight sensor, the clamp position motor 1050 may be adjusted to find a center of balance by laterally adjusting the position of the imaging device, which may be determined based upon the strain gauges or otherwise (and may include loosening and tightening the clamp with the clamp lock motor 1040). After adjusting the lateral position of the imaging device the tilt motor 1000 may adjust the tilt of the imaging device (with the tilt lock motor 1020 released) and head to a suitable angular position, such as 45 degrees. With the head at an angular position with respect to the base, a counterbalance motor 1030 adjusts the counterbalance of the head until a suitable balance is determined. The head is then tilted back to a horizontal position using the tilt motor 1000, a damping adjustment may be made, and the mounting is then calibrated and suitable for being used. The operation of each of the motors may be under control from the microcontroller 460 with signals sensed from suitable sensors by the microcontroller 460. The aspects of the calibration may be performed in any suitable order of operation, and selected elements may be omitted, and some of the operations may be manual or automated.

If desired, a fully or semi-fully automated calibration system may be implemented using one or more of the motors 1000, 1010, 1020, 1030, 1040, 1050, 1060. For example, by selecting a calibration button, the mounting may automatically initiate the calibration process by automatically adjusting the level of the base using the base motor 1060, automatically locking the panning base using the panning motor 1010 if desired, and automatically bringing the head into a horizontal orientation using the tilt motor 1000. With the head in the horizontal orientation the clamp is opened using the clamp lock motor 1040 to receive the imaging device, and upon sensing the imaging device is engaged with the clamp, the clamp lock motor 1040 locks the clamp and the imaging device thereon. The balance of the imaging device is then automatically adjusted using the clamp position motor 1050, the tilt of the head is automatically adjusted using the tilt motor 1000, the counterbalance of the head is automatically adjusted using the counterbalance motor, and then the head it automatically returned to a horizontal position using the tilt motor 1000. In this manner, all or several aspects of the calibration process may be achieved in an automated manner.

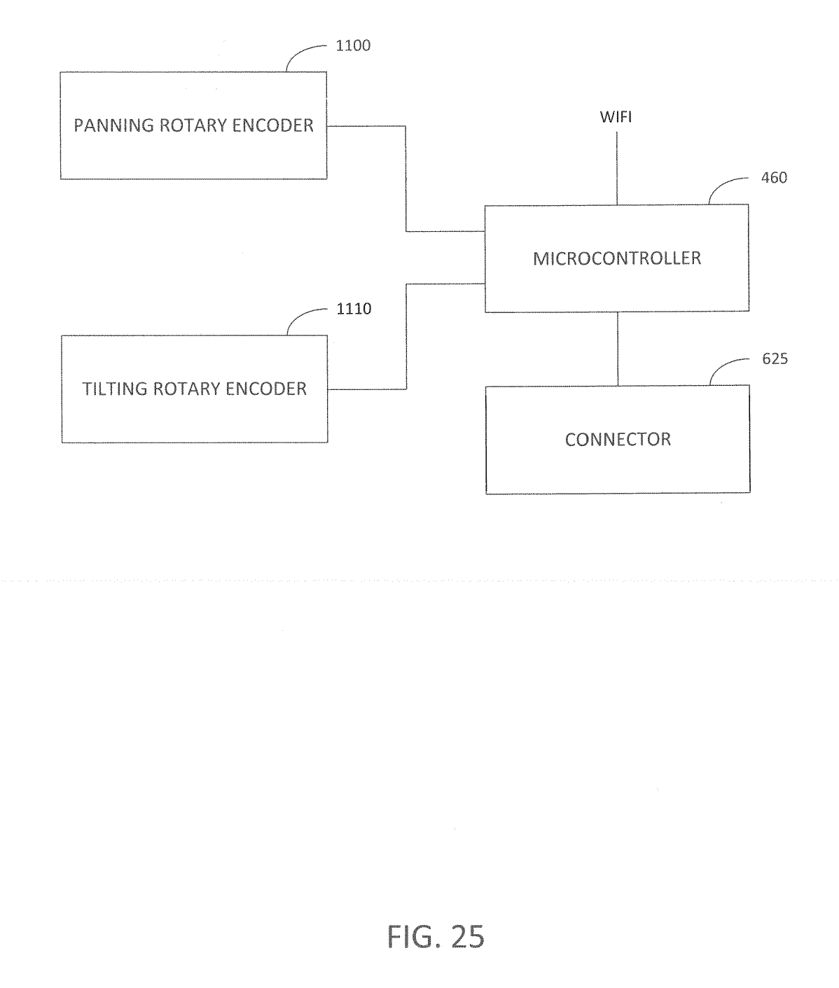

The motion over which the mounting device moves over a period of time, which is related to the scene that is observed by the imaging device supported thereon over a period of time, is related to the three dimensional view of the scene. Referring to FIG. 25, a panning rotary encoder 1100 may be used to sense the rotation of the tilting head relative to the base and a tilting rotary encoder 1110 may be used to sense the tilting of the tiling head relative to the base. The data from each of the encoders 1100, 1110 may be provided to the microcontroller 460. With the combination of both the panning rotary encoder 1100 and the tilting rotary encoder 1110, the three dimensional viewpoint of the scene may be determined from a fixed point, such as the top of a tripod. During the capture of a set of images, or otherwise a video sequence, a set of angular data over a temporal time period may be gathered based upon the panning rotary encoder 1100 and the tilting rotary encoder 1110. The angular data may be for each of the encoders 1100, 1110, or may be combined into a three dimensional set of angular data, as desired. The data may be stored by the microcontroller 460 and may be provided from the microcontroller 460 to an external device, such as through a connector 625 under a cover 635 on the mounting or a wireless signal.

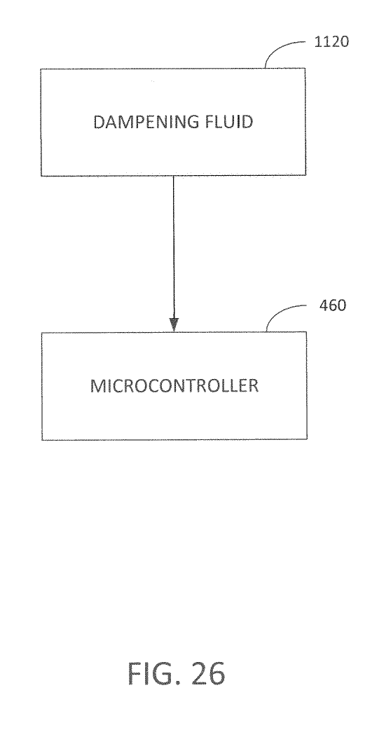

In another embodiment, a dampening may be included together with the mounting. In some situations, it is desirable to modify the dampening of the mounting. While the user may modify the dampening, such as by turning a collar on the mounting, there are situations where it is desirable to modify the dampening without user intervention to reduce the vibration of the mounting. Referring to FIG. 26, preferably the dampening is provided by a dampening fluid 1120. Preferably the dampening fluid may be a colloidal liquid, or otherwise, made of nanoscale ferromagnetic, ferromagnetic, or other particles suspended in a carrier fluid, where the viscosity of the fluid may be modified based upon electrical and/or magnetic fields. The microcontroller 460 may selectively provide modified electrical and/or magnetic fields to the dampening fluid 1120. The modified viscosity of the dampening fluid 1120 results in modifying the dampening of the mounting. The microcontroller 460 may determine appropriate modification of the dampening based upon usage, or may be externally controlled by way of wifi or the connector 625.

The detailed description, above, sets forth numerous specific details to provide a thorough understanding of the present invention. However, those skilled in the art will appreciate that the present invention may be practiced without these specific details. In other instances, well known methods, procedures, components, and circuitry have not been described in detail to avoid obscuring the present invention.

All the references cited herein are incorporated by reference.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

What is claimed is:

1. A mounting assembly suitable to support an imaging device thereon and suitable to be supported by a tripod comprising:
(a) said mounting assembly including a tiltable structure suitable for supporting said imaging device only capable of being tilted along a single tiltable axis;
(b) said mounting assembly including a base supporting said tiltable structure suitable to be supported by said tripod that is rotatable only along a single rotary axis generally perpendicular to said tiltable axis;
(c) said mounting assembly further including at least one of:
(i) said mounting assembly including a bubble level, said mounting assembly including a battery enclosed within a housing, said mounting assembly including an illumination source, and said mounting assembly including a trigger mechanism where triggering said trigger mechanism results in electrically interconnecting said battery source with said illumination source in a manner that illuminates said illumination source to provide illumination from within said bubble level for a predetermined period of time and automatically electrically disconnects said battery source from said illumination source after said predetermined period of time;
(ii) said mounting assembly including a set of markings on at least one of said tiltable structure and said base such that tilting of said tiltable structure indicates an amount of tilt of said tiltable structure relative to said base, and said mounting assembly including a rotary encoder that determines an amount of tilt of said tillable structure relative to said base that is displayed on a display supported by said mounting assembly;
(iii) said tiltable structure supporting a clamp thereon that defines an engagement region that includes at least one movable jaw suitable to selectively engage an imaging device within said engagement region, and said clamp including a movable member with a first portion of said movable member extending within said engagement region in a manner such that when an imaging device is placed within said engagement region a second portion of said movable member engages said imaging device;
(iv) said mounting assembly including a trigger mechanism operable when said mounting assembly is determined to have said tiltable structure inhibited from being tilted, and an indicator selectively indicating whether said imaging device is balanced on said mounting assembly based upon said trigger mechanism;
(v) said mounting assembly including a trigger mechanism operable when said mounting assembly is determined to have said tiltable structure inhibited from being tilted, and an indicator selectively indicating a counterbalance indication on said mounting assembly based upon said trigger mechanism;
(vi) said mounting assembly distinguishing between a first state when said mounting assembly is determined to have said tiltable structure inhibited from being tilted at a first angular orientation and a second state when said mounting assembly is determined to have said tiltable structure inhibited from being tilted at a second angular orientation;
(vii) said mounting assembly including a weight sensor suitable to determine the weight related to said imaging device supported by said mounting assembly, and an indicator indicating a weight of said imaging device based upon said weight sensor;
(viii) said mounting assembly including a temperature sensor suitable to determine a temperature proximate to said mounting assembly, and an indicator indicating said temperature proximate said mounting assembly based upon said temperature sensor;
(ix) said mounting assembly including a battery sensor suitable to determine a battery level of a battery enclosed within said mounting assembly, and an indicator indicating said battery level of said battery based upon said battery sensor;
(x) said mounting assembly including a battery sensor suitable to determine a battery compatibility of a battery enclosed within said mounting assembly, and an indicator indicating said battery compatibility of said battery based upon said battery sensor;
(xi) said mounting assembly including a rotary encoder that determines an amount of tilt of said tillable structure relative to said base that is displayed on a display supported by said mounting assembly, where said rotary encoder determines said amount of tilt independent of whether battery power is provided to said mounting assembly;
(xii) a triggering mechanism that when activated automatically results in all of the following, (i) leveling said base with respect to a horizontal plane, (ii) inhibiting rotation of said base with respect to said tiltable structure, (iii) tilting said tiltable structure along said single tiltable axis to be generally co-planar with said base, (iv) opening a clamp suitable to receive said imaging device thereon after said leveling said base, (v) closing said clamp in response to receiving said imaging device suitable to retain said imaging device thereon after said leveling said base, (vi) balancing said imaging device on said clamp by lateral movement of said imaging device after leveling said base, (vii) tilting said tiltable structure along said single tiltable axis to a generally inclined angle with respect to said base after said balancing, (viii) adjusting a counterbalance of said tiltable structure after said balancing, and (ix) tilting said tillable structure along said single tiltable axis to be generally co-planar with said base after said adjusting said counterbalance;
(xiii) said mounting assembly determining a counterbalance value for said imaging device being supported thereon based upon said tiltable structure assembly being tilted with an imaging device supported thereon;
(xiv) said mounting assembly including a tilting rotary encoder that determines an amount of tilt of said tillable structure relative to said base, said mounting assembly including a panning rotary encoder that determines an amount of panning of said tillable structure relative to said base, and a controller that provides said amount of tilt and said amount of panning to an external device to said mounting; and
(xv) said mounting assembly including dampening fluid therein that modifies the drag between said base and said tiltable structure based upon a viscosity of said dampening fluid, and a controller that selectively provides a signal to said dampening fluid to selectively at least one of increase and decrease said viscosity of said dampening fluid.

2. The mounting assembly of claim 1 comprising said mounting assembly including,
(a) said mounting assembly including said bubble level;
(b) said mounting assembly including said battery enclosed within said housing;
(c) said mounting assembly including said illumination source;
(d) said mounting assembly including said trigger mechanism where triggering said trigger mechanism results in electrically interconnecting said battery source with said illumination source in said manner that illuminates said illumination source to provide illumination from within said bubble level for said predetermined period of time and automatically electrically disconnects said battery source from said illumination source after said predetermined period of time.

3. The mounting assembly of claim 1 comprising said mounting assembly including,
(a) said mounting assembly including said set of markings on at least one of said tiltable structure and said base such that tilting of said tiltable structure indicates said amount of tilt of said tiltable structure relative to said base;
(b) said mounting assembly including said rotary encoder that determines said amount of tilt of said tillable structure relative to said base that is displayed on said display supported by said mounting assembly.

4. The mounting assembly of claim 1 comprising said mounting assembly including,
(a) said tiltable structure supporting said clamp thereon that defines said engagement region that includes at least one movable jaw suitable to selectively engage said imaging device within said engagement region;
(b) said clamp including said movable member with said first portion of said movable member extending within said engagement region in said manner such that when said imaging device is placed within said engagement region said second portion of said movable member engages said imaging device.

5. The mounting assembly of claim 1 comprising said mounting assembly including,
(a) said mounting assembly including said trigger mechanism operable when said mounting assembly is determined to have said tiltable structure inhibited from being tilted;
(b) said indicator selectively indicating whether said imaging device is balanced on said mounting assembly based upon said trigger mechanism.

6. The mounting assembly of claim 1 comprising said mounting assembly including,
(a) said mounting assembly including said trigger mechanism operable when said mounting assembly is determined to have said tiltable structure inhibited from being tilted;
(b) said indicator selectively indicating said counterbalance indication on said mounting assembly based upon said trigger mechanism.

7. The mounting assembly of claim 1 comprising said mounting assembly including,
(a) said mounting assembly distinguishing between said first state when said mounting assembly is determined to have said tiltable structure inhibited from being tilted at said first angular orientation and said second state when said mounting assembly is determined to have said tiltable structure inhibited from being tilted at said second angular orientation.

8. The mounting assembly of claim 1 comprising said mounting assembly including,
(a) said mounting assembly including said weight sensor suitable to determine the weight related to said imaging device supported by said mounting assembly;
(b) said indicator indicating said weight of said imaging device based upon said weight sensor.

9. The mounting assembly of claim 1 comprising said mounting assembly including,
(a) said mounting assembly including said temperature sensor suitable to determine said temperature proximate to said mounting assembly;
(b) said indicator indicating said temperature proximate said mounting assembly based upon said temperature sensor.

10. The mounting assembly of claim 1 comprising said mounting assembly including,
(a) said mounting assembly including said battery sensor suitable to determine said battery level of said battery enclosed within said mounting assembly;
(b) said indicator indicating said battery level of said battery based upon said battery sensor.

11. The mounting assembly of claim 1 comprising said mounting assembly including,
(a) said mounting assembly including said battery sensor suitable to determine said battery compatibility of said battery enclosed within said mounting assembly;
(b) said indicator indicating said battery compatibility of said battery based upon said battery sensor.

12. The mounting assembly of claim 1 comprising said mounting assembly including,
(a) said mounting assembly including said rotary encoder that determines said amount of tilt of said tillable structure relative to said base that is displayed on said display supported by said mounting assembly, where said rotary encoder determines said amount of tilt independent of whether battery power is provided to said mounting assembly.

13. The mounting assembly of claim 1 comprising said mounting assembly including,
(a) said triggering mechanism that when activated automatically results in all of the following,
(i) leveling said base with respect to said horizontal plane;
(ii) inhibiting rotation of said base with respect to said tiltable structure;
(iii) tilting said tiltable structure along said single tiltable axis to be generally co-planar with said base;
(iv) opening said clamp suitable to receive said imaging device thereon after said leveling said base;
(v) closing said clamp in response to receiving said imaging device suitable to retain said imaging device thereon after said leveling said base;
(vi) balancing said imaging device on said clamp by lateral movement of said imaging device after leveling said base;
(vii) tilting said tiltable structure along said single tiltable axis to said generally inclined angle with respect to said base after said balancing;
(viii) adjusting said counterbalance of said tiltable structure after said balancing;
(ix) tilting said tillable structure along said single tiltable axis to be generally co-planar with said base after said adjusting said counterbalance.

14. The mounting assembly of claim 1 comprising said mounting assembly including,
(a) said mounting assembly determining said counterbalance value for said imaging device being supported thereon based upon said tiltable structure assembly being tilted with said imaging device supported thereon.

15. The mounting assembly of claim 1 comprising said mounting assembly including,
(a) said mounting assembly including said tilting rotary encoder that determines said amount of tilt of said tillable structure relative to said base;
(b) said mounting assembly including said panning rotary encoder that determines said amount of panning of said tillable structure relative to said base;
(c) said controller that provides said amount of tilt and said amount of panning to said external device to said mounting.

16. The mounting assembly of claim 1 comprising said mounting assembly including,
(a) said mounting assembly including dampening fluid therein that modifies said drag between said base and said tiltable structure based upon said viscosity of said dampening fluid;
(b) said controller that selectively provides said signal to said dampening fluid to selectively at least one of increase and decrease said viscosity of said dampening fluid.
